(19) United States
(12) Patent Application Publication
(10) Pub. No.: US 2017/0178999 A1
(43) Pub. Date: Jun. 22, 2017

(54) FLIP-CHIP PACKAGE WITH THERMAL DISSIPATION LAYER

(71) Applicant: Intel IP Corporation, Santa Clara, CA (US)

(72) Inventors: Richard Patten, Langquaid (DE); Bernd Waidhas, Pettendorf (DE); Sonja Koller, Regensburg (DE)

(21) Appl. No.: 14/977,307

(22) Filed: Dec. 21, 2015

(51) Int. Cl. H01L 23/373; H01L 23/31

(52) U.S. Cl. CPC H01L 23/3736; H01L 23/3114

(57) ABSTRACT

Embodiments herein may relate to a flip-chip chip scale package (FCCSP) with a thermal dissipation layer to dissipate heat from the FCCSP during operation of the FCCSP. The thermal dissipation layer may be applied to a surface of the FCCSP through a sputter coating process and may operate as a heat spreader for the FCCSP. Other embodiments may be described and/or claimed.

### TECHNICAL FIELD

The present disclosure relates generally to the field of flip-chip chip scale packages (FCCSPs), and more specifically to a flip-chip chip scale package with a thermal dissipation layer.

### BACKGROUND

Legacy FCCSPs did not produce enough heat to require a heat spreader for dissipating heat. However, as the FCCSPs are reduced in size, the FCCSPs can generate enough heat to cause errors, failure of and/or damage to the FCCSP. In order to address these issues, it has become desirable to attach a heat spreader to the FCCSP. Legacy versions of heat spreaders for the FCCSPs include placing a contact metal slug on the FCCSP, although the process of attaching the contact metal slug is difficult and expensive, as well as increasing the overall thickness of the FCCSP.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional view of a portion of an example FCCSP assembly that includes an FCCSP with a thermal dissipation layer, in accordance with various embodiments.

FIG. 2 is an example sputter coating process of applying the thermal dissipation layer to a portion of an FCCSP, in accordance with various embodiments.

FIG. 3 is a cross-sectional view of another portion of an example FCCSP assembly that includes an FCCSP with a thermal dissipation layer, in accordance with various embodiments.

FIG. 4 is a cross-sectional view of a portion of an example FCCSP assembly that includes an FCCSP with an electrolytic plating layer, in accordance with various embodiments.

FIG. 5 is a cross-sectional view of a portion of an example FCCSP assembly that includes an FCCSP with a flash coat layer and a protective layer, in accordance with various embodiments.

FIG. 6 is an example process for making an FCCSP assembly that includes an FCCSP with a thermal dissipation layer, in accordance with various embodiments.

FIG. 7 is an example computing device, in accordance with various embodiments.

### DETAILED DESCRIPTION

Embodiments herein may relate to achieving desired heat dissipation of an FCCSP within a limited FCCSP thickness requirement by applying a thermal dissipation layer to a surface of the FCCSP. The thermal dissipation layer may be applied to the surface of the FCCSP through a sputter coating process or a polymer spray coating process, where the thermal dissipation layer provides adequate thermal dissipation while limiting an increase in the thickness of the FCCSP due to the thermal dissipation layer.

Legacy heat spreaders may have included a contact metal slug affixed to an FCCSP to dissipate heat created by the FCCSP during operation. However, the contact metal slug may have a relatively large thickness and, as a result, the total thickness of the contact metal slug and the FCCSP may be increased by a relatively large amount, such that the FCCSP may not fit within a desired installation location due to the thickness of the FCCSP. Embodiments herein may allow for application of a thermal dissipation layer that acts as a heat spreader with characteristics similar to legacy heat spreaders, although having a fraction of the thickness of the legacy heat spreaders.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” “in some embodiments,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

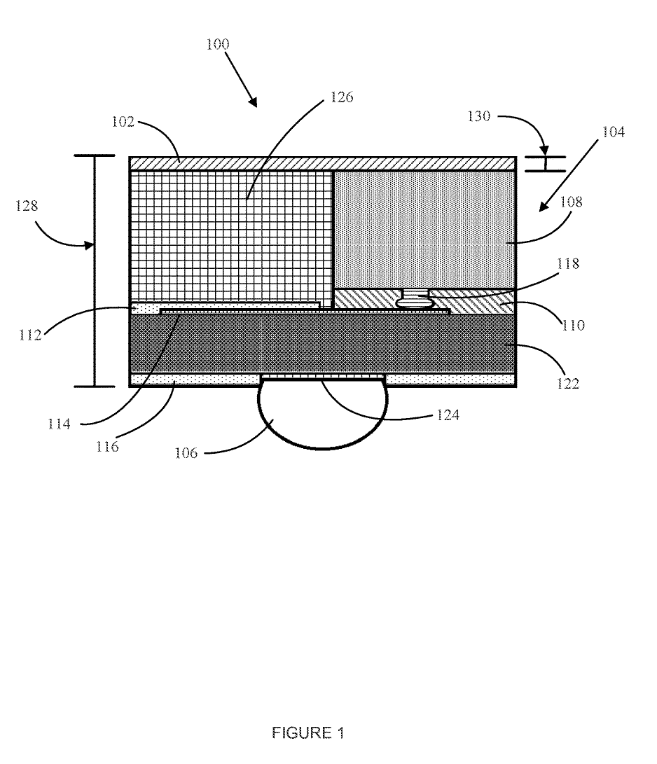

FIG. 1 depicts a portion of an example flip-chip chip scale package (FCCSP) assembly 100 that includes an FCCSP 104 with a thermal dissipation layer 102. The FCCSP 104 may include some type of flip-chip package design, including package designs produced through the use of a capillary underfill process, a molded underfill process, some other process, or some combination thereof. The FCCSP 104 may be designed and/or utilized for certain operations, such as broadband use or digital use.

The FCCSP 104 may be manufactured through some known manufacturing technique and/or process for producing a chip package. In examples, the process of producing the FCCSP 104 may include laser marking the FCCSP 104 prior to application of the thermal dissipation layer 102. The laser marking may be utilized for identifying the FCCSP 104, indicating characteristics of the FCCSP 104, other elements that may be indicated by a laser marking, and/or some combination thereof. The laser marking applied to the FCCSP 104 may be visible through and/or on the thermal dissipation layer 102. In examples, the FCCSP 104 and/or the thermal dissipation layer 102 may be marked after application of the thermal dissipation layer 102, such as by using ink, laser marking, other known forms of marking chips, or some combination thereof.

The FCCSP 104 may include one or more components, substrates, layers, or some combination thereof. The FCCSP 104 may include a chip 108 abutted on a side by an underfill material 110. The chip 108 may be electrically coupled to a substrate layer 122 by first level interconnects 118. The substrate layer 122 may include one or more pre-preg layers, core layers, electrically conductive inner layers, via structures, or some combination thereof.

The first level interconnects 118 may extend through the underfill material 110 and may contact an electrically conductive trace 114, the electrically conductive trace 114 at least partially located intermediate to underfill material 110 and the substrate layer 122. Solder resist 116 may be affixed to a surface of the substrate layer 122. Additionally, the FCCSP may include an encapsulation material 126 and a solder resist 112, the solder resist located intermediate to the encapsulation material 126 and the electrically conductive trace 114.

A solder ball 106 may be affixed to a surface of the FCCSP 104. The surface of the FCCSP 104 to which the solder ball 106 is affixed may include thermally conductive traces and ball pads 124. In some embodiments, the solder ball 106 may also be referred to as a solder “bump.” Generally, as used herein, a solder ball or solder bump may refer to the solder material itself, either in its pre- or post-reflow state. The surface of the FCCSP 104 to which the solder ball 106 is affixed may be orientated toward a circuit board when the FCCSP 104 is mounted to the circuit board. When mounting the circuit board, the solder ball 106 may be subjected to a reflow process for affixing the FCCSP 104 to the circuit board.

The thermal dissipation layer 102 may be affixed to another surface of the FCCSP 104. As shown, the thermal dissipation layer 102 may be affixed to a surface of the FCCSP 104 opposing the solder ball 106. In embodiments, the thermal dissipation layer 102 may be affixed to a single surface to which the solder ball 106 is not affixed or some combination of the surfaces to which the solder ball 106 is not affixed. Further, in embodiments, the thermal dissipation layer 102 may be affixed to the same surface as the solder ball 106 and may extend across the surface surrounding the solder ball 106 without contacting the solder ball 106. The thermal dissipation layer 102 may be affixed in a configuration such that the thermal dissipation layer 102 is electrically isolated from a ground of the FCCSP 104, signals of the FCCSP 104, circuitry of the FCCSP 104, or some combination thereof.

The thermal dissipation layer 102 may be affixed to the surface of the FCCSP 104 through a sputter coating process. The sputter coating process may include some sputter coating process now known or later developed, including the simplified example sputter coating process described in more detail below.

The thermal dissipation layer 102 may include a metallic element or combination of metallic elements that may be subjected to the sputter coating process. The thermal dissipation layer 102 may be a type of metal with a high thermal conductivity, including silver, copper, aluminum, zinc, iron, tin, or some combination thereof. For example, the thermal dissipation layer 102 may be copper applied to the surface of the FCCSP 104 through the sputter coating process.

In other examples, the thermal dissipation layer 102 may be affixed to the surface of the FCCSP 104 through a polymer spray coating process. In these examples, the thermal dissipation layer 102 may be a type of polymer with a high thermal conductivity, including graphite, thermally conductive plastics, polymers with high molecular weight polyethylene nanofibers, polymers with vapor grown carbon fiber, or some combination thereof.

In some examples, the thermal dissipation layer 102 may be affixed to the surface of the FCCSP 104 through a laminating process. In these examples, the thermal dissipation layer 104 may include a thermally conductive material. The thermally conductive material may include materials with high thermal conductivity including some type of metallic material (such as silver, copper, aluminum, zinc, iron, tin, or some combination thereof), graphite, thermally conductive plastics, polymers with high molecular weight polyethylene nanofibers, polymers with vapor grown carbon fiber, or some combination thereof.

The thermal dissipation layer 102 may operate as a heat spreader during operation of the FCCSP 104, thereby dissipating heat produced by the FCCSP 104 during operation. The thermal dissipation may increase or decrease based on the thickness of the thermal dissipation layer 102, the type of metal and/or polymer comprising the thermal dissipation layer 102, the density of the thermal dissipation layer 102, some other factor, and/or some combination thereof.

A thickness of the thermal dissipation layer 102 may be selected based on one or more factors, including a desired heat dissipation achieved by the thermal dissipation layer 102, a desired maximum combined thickness of the FCCSP and the thermal dissipation layer 128, a desired thickness of the thermal dissipation layer 130, some other factor and/or some combination thereof. In an embodiment, the thickness of the thermal dissipation layer 102 may be selected such that the combined thickness of the FCCSP and the thermal dissipation layer 128 is approximately, or less than, 800 micrometers. In an embodiment, the thickness of the thermal dissipation layer 130 may be limited to a maximum of 20 micrometers. A thickness of the thermal dissipation layer 102 may vary across the surface and/or surfaces of the FCCSP 104 based on the sputter coating process utilized, a direction from which the thermal dissipation layer 102 was applied during the sputter coating process, an angle that the surface to which the thermal dissipation layer 102 was applied was toward a target material utilized for applying the thermal dissipation layer 102 during the sputter coating process, varying desired heat dissipation amounts along different portions of the surface or surfaces, some other factor, or some combination thereof.

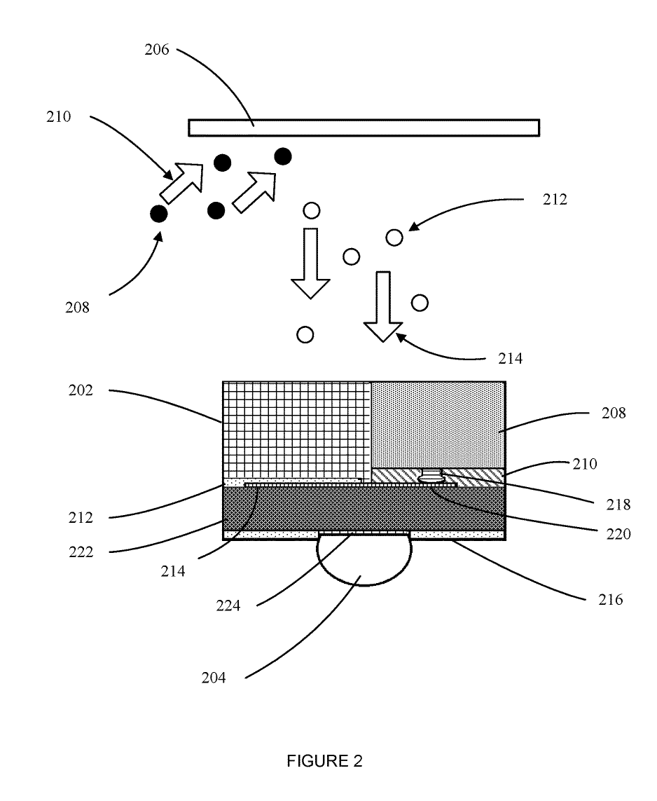

FIG. 2 depicts an example sputter coating process of applying a thermal dissipation layer, such as thermal dissipation layer 102 of FIG. 1, to a portion of an FCCSP 202, such as FCCSP 104 of FIG. 1. The FCCSP 202 may include a solder ball 204, such as solder ball 106 of FIG. 1, affixed to a surface of the FCCSP 202.

A target material 206 may be placed in a vacuum chamber (not shown). The target material 206 may include a material to be applied to the FCCSP 202 as a thermal dissipation layer (e.g., thermal dissipation layer 102), as discussed throughout this disclosure, including silver, copper, aluminum, zinc, iron, tin, or some combination thereof.

During the sputter coating process, the target material 206 may be bombarded with gas atoms 208, such as argon atoms, oxygen atoms, other heavy gas atoms, or some combination thereof. The gas atoms 208 may be directed toward the target material 206 in a direction 210.

In response to the gas atoms 208 contacting the target material 206, target ions 212 may be ejected from the target material 206. The target ions 212 may be ejected in a direction 214 toward the FCCSP 202. Upon contact with the FCCSP 202, the target ions 212 may become affixed to the FCCSP 202, to other target ions 212 already affixed to the FCCSP 202, some other material residing on the surface of the FCCSP, or some combination thereof. As an increasing amount of the target ions 212 become affixed to the FCCSP 202 and/or the other target ions 212, a thermal dissipation layer, such as the thermal dissipation layer 102 of FIG. 1, may be produced on a surface of the FCCSP 202.

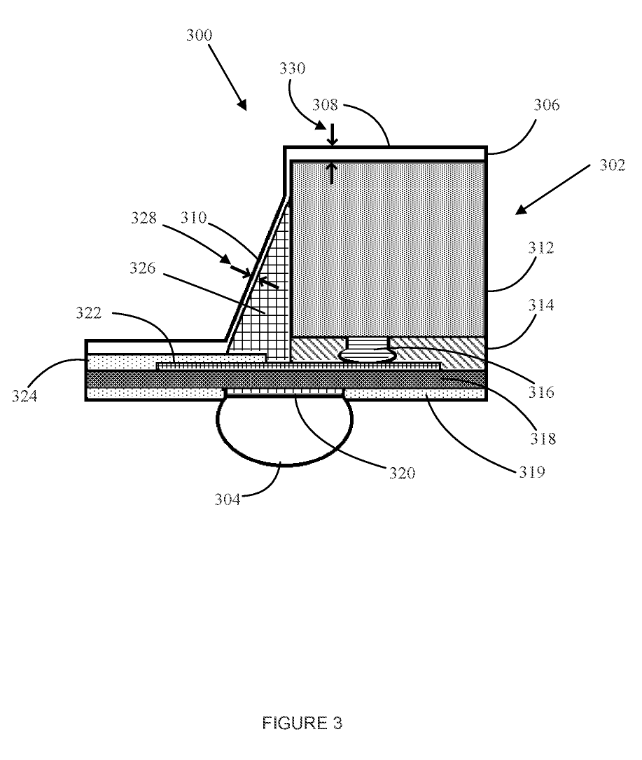

FIG. 3 depicts a cross-sectional view of another portion of an example FCCSP assembly 300 that includes an FCCSP 302 with a thermal dissipation layer 306. The FCCSP assembly 300 may include one or more features to the similar features of the FCCSP assembly 100 of FIG. 1.

The FCCSP 302 may include one or more components, substrates, layers, or some combination thereof. The FCCSP 302 may include a chip 312 abutted on a side by an underfill material 314. The chip 312 may be electrically coupled to a substrate layer 318 by first level interconnects 316. The substrate layer 318 may include one or more pre-preg layers, core layers, electrically conductive inner layers, via structures, or some combination thereof.

The first level interconnects 316 may extend through the underfill layer 314 and may contact an electrically conductive trace 322, the electrically conductive trace 322 at least partially located intermediate to the under fill layer 314 and the substrate layer 318. Solder resist 319 may be affixed to a surface of the substrate layer 318. Additionally, the FCCSP 302 may include an encapsulation material 326 and a solder resist 324, the solder resist 324 located intermediate to the encapsulation material 326 and the substrate layer 318.

The thermal dissipation layer 306 may be affixed to the FCCSP 302 on a surface of the FCCSP 302 opposite a solder ball 304 affixed to the FCCSP 302. The solder ball 304 may be affixed to a surface of the FCCSP 302 that includes thermally conductive traces and ball pads 320. In embodiments, the thermal dissipation layer 306 may be affixed to one surface or a combination of the surfaces of the FCCSP 302.

The thermal dissipation layer 306 may extend across a flat portion 308 and a slanted portion 310 of the surface of the FCCSP 302. The thickness of the thermal dissipation layer 306 may differ between the flat portion 308 and the slanted portion 310 of the FCCSP 302. The thickness of the flat portion 330 of the thermal dissipation layer 306 may be approximately 20 micrometers, while the thickness of the slanted portion 328 may be approximately 10 micrometers. The difference in the thickness between the flat portion 308 and the slanted portion 310 may be based on the process used for applying the thermal dissipation layer 306, the orientation of the FCCSP 302 toward a target material during a sputter coating process, or some combination thereof.

In embodiments, the thermal dissipation layer 306 may be substantially the same thickness on the flat portion 308 and the slanted portion 310. In order to achieve the same thickness on the flat portion 308 and the slanted portion 310, the orientation of the FCCSP 302 toward the target material during the sputter coating process may be changed, such that a greater portion of the target ions, such as target ions 212 of FIG. 2, are directed toward the flat portion 308 in a first orientation and a greater portion of the target ions are directed to the slanted portion 310 in a second orientation.

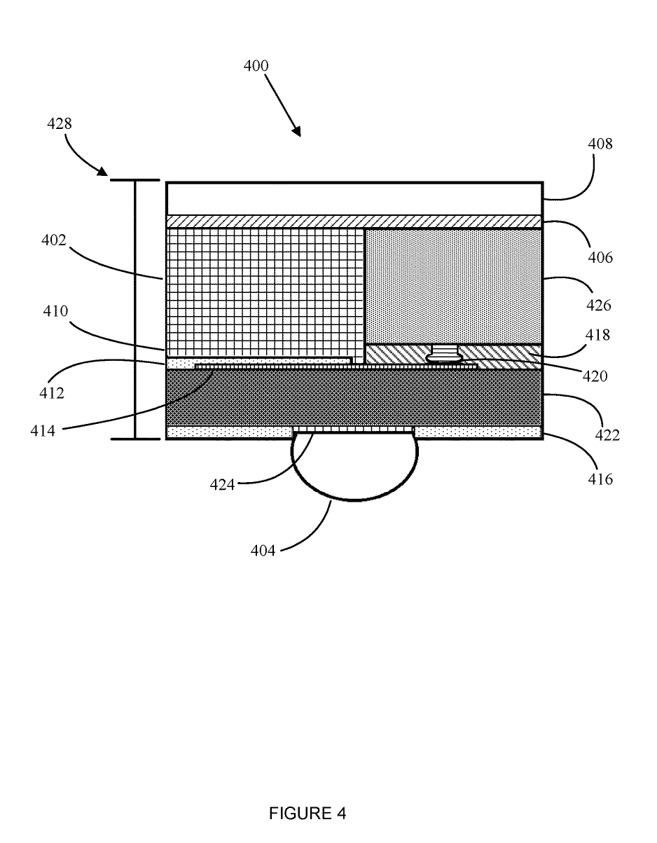

FIG. 4 depicts a cross-sectional view of a portion of an example FCCSP assembly 400 that includes an FCCSP 402 with an electrolytic plating layer 408. The FCCSP assembly 400 may include one or more features similar to the features of the FCCSP assembly 100 of FIG. 1 and/or the FCCSP assembly 300 of FIG. 3.

A thermal dissipation layer 406 may be affixed to the FCCSP 402 on a surface opposite a solder ball 404 affixed to the FCCSP 402. In embodiments, the thermal dissipation layer 406 may be affixed to one surface or a combination of the surfaces of the FCCSP 402.

The electrolytic plating layer 408 may be affixed to the thermal dissipation layer 406 on a surface of the thermal dissipation layer 406 opposite the surface of the thermal dissipation layer 406 affixed to the FCCSP 402. In embodiments, the electrolytic plating layer 408 may be affixed to one or more of the surfaces of the thermal dissipation layer 406 that are not affixed to the FCCSP 402. The electrolytic plating layer 408 may be affixed to an entirety or a portion of the one or more of the surfaces of the thermal dissipation layer 406. The electrolytic plating layer 408 may be affixed to the thermal dissipation layer through an electrolytic plating process.

The electrolytic plating layer 408 may be a type of material having a high thermal conductivity, such as silver, copper, aluminum, zinc, iron, tin, or some combination thereof. Affixing the electrolytic plating layer 408 may increase the thermal dissipation of the FCCSP assembly 400 during operation of the FCCSP 402.

A thickness of the electrolytic plating layer 408 may be selected based on a desired amount of heat dissipation of the FCCSP assembly 400 during the operation of the FCCSP 402. In other embodiments, the thickness of the electrolytic plating layer 408 may be selected based on a desired maximum thickness of the FCCSP assembly 400. The thickness of the FCCSP assembly 428, including the FCCSP 402, the thermal dissipation layer 406, and the electrolytic plating layer 408 may be approximately, or less than, 800 micrometers.

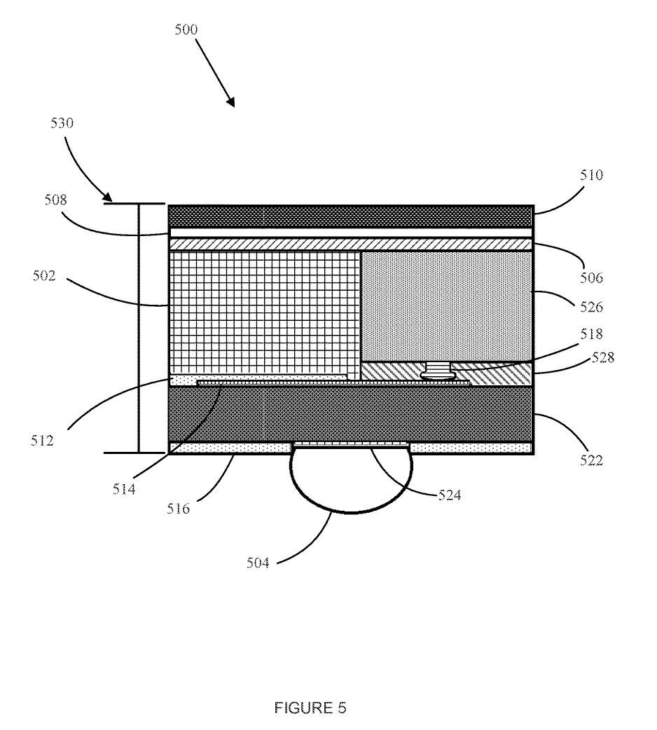

FIG. 5 depicts a cross-sectional view of a portion of an example FCCSP assembly 500 that includes an FCCSP 502 with a flash coat layer 508 and a protective layer 510. The FCCSP assembly 500 may include one or more features similar to the features of the FCCSP assembly 100 of FIG. 1, the FCCSP assembly 300 of FIG. 3, and/or the FCCSP assembly 400 of FIG. 4.

A thermal dissipation layer 506 may be affixed to the FCCSP 502 on a surface opposite a solder ball 504 affixed to the FCCSP 502. In embodiments, the thermal dissipation layer 506 may be affixed to one or a combination of the surfaces of the FCCSP 502.

The flash coat layer 508 may be affixed to a surface of the thermal dissipation layer 506 opposite a surface of the thermal dissipation layer 506 affixed to the FCCSP 502. The flash coat layer 508 may be affixed to an entirety or a portion of the thermal dissipation layer 506 not affixed to the FCCSP 502. The flash coat layer 508 may be applied to the thermal dissipation layer 506 through a flash coating process.

The flash coat layer 508 may be applied to the thermal dissipation layer 506 to protect the thermal dissipation layer 506 from oxidization. The flash coat layer 508 may comprise a metal, including nickel, zinc, or some combination thereof.

The protective layer 510 may be affixed to a surface of the flash coat layer 508 opposite the surface of the flash coat layer 508 affixed to the thermal dissipation layer 506. The protective layer 510 may be affixed to an entirety or a portion of the flash coat layer 508 not affixed to the thermal dissipation layer 506.

The protective layer 510 may protect the flash coat layer 508, the thermal dissipation layer 506, the FCCSP 502, or some combination thereof from physical damage. The protective layer 510 may be a metal, including stainless steel, steel, iron, silver, or some combination thereof. In some embodiments, the protective layer 510 may be forgone, leaving the FCCSP 502 with the flash coat layer 508.

Thicknesses of the flash coat layer 508 and/or the protective layer 510 may be selected based on a maximum desired thickness of the FCCSP assembly 500. The thicknesses of the flash coat layer 508 and the protective layer 510 may be selected such that a thickness of the FCCSP assembly 530, including the FCCSP 502, the thermal dissipation layer 506, the flash coat layer 508 and the protective layer 510, is approximately, or less than, 800 micrometers. In embodiments where the protective layer 510 has been forgone, the FCCSP assembly 500, including the FCCSP 502, the thermal dissipation layer 506 and the flash coat layer 508, may have a combined thickness of approximately, or less than, 800 micrometers.

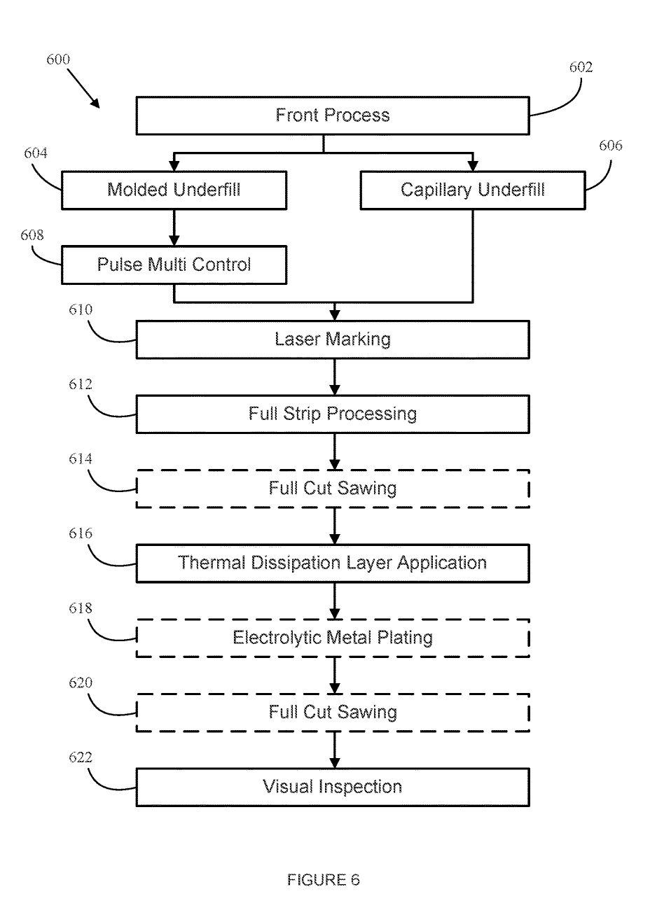

FIG. 6 depicts an example process 600 for making an FCCSP assembly that includes an FCCSP with thermal dissipation layer. The example process 600 may be utilized to produce the FCCSP assembly 100 of FIG. 1, the FCCSP assembly 300 of FIG. 3, the FCCSP assembly 400 of FIG. 4, and/or the FCCSP assembly 500 of FIG. 5.

The example process 600 may be similar to known processes for producing an FCCSP, with the exception of the additional thermal dissipation layer application block. The process 600 may begin with a front process block 602 for producing a base die of the FCCSP. The front process block 602 may include an incoming wafer. The incoming wafer may be subjected to a process of back-grinding and dicing. A die may be attached to the processed wafer and a substrate may be reflowed on to the wafer. The substrate may be subjected to a process of de-fluxing and cleaning to produce the base die.

The process 600 may alternatively continue to either a molded underfill block 604 or a capillary underfill block 606 for underfilling the base die. In the molded underfill block 604, a mold compound is forced under the base die. The mold compound is subjected to a post mold cure process to fully cross link the mold compound material. If the molded underfill block 604 is used, the process 600 continues to a pulse multi control block 608.

After completion of the underfill blocks, the process 600 continues to a laser marking block 610. A laser marking may be applied to the top surface of the FCCSP for identification. The FCCSP is laser marked with identification information or information identifying characteristics of the FCCSP. The laser mark generated by the laser marking block 610 may be visible through or on the thermal dissipation layer of the completed FCCSP.

The process continues to a full strip processing block 612. The full strip processing block 612 may indicate that the process 600 is being applied to a substrate strip of FCCSPs. In some embodiments, the process 600 may continue to a full cut sawing block 614. In other embodiments, the full cut sawing block 614 is forgone until a later stage in the process 600.

In block 616, the thermal dissipation layer is applied. The thermal dissipation layer may be applied by the techniques and/or the configurations described in this disclosure, including the sputter metal coating process and/or the polymer spray coating process.

In some embodiments, the process 600 continues to an electrolytic metal plating block 618 in order to add an electrolytic plating layer, such as electrolytic plating layer 408 of FIG. 4. The electrolytic metal plating block 618 may include a plating process, where additional metal may be plated to a surface of the FCCSP. The additional metal may include any thermally conductive metal, including silver, copper, aluminum, zinc, iron, tin, or some combination thereof. The electrolytic player layer block 618 may be forgone in some of the embodiments where the thermal dissipation layer is only desired to be affixed to the FCCSP.

The process 600 may then continue to a full cut sawing block 620 in some embodiments. The full cut sawing block 614 and the full cut sawing block 620 may be utilized in different embodiments of the process 600 from each other. For instance, some of the embodiments of the process 600 may include full cut sawing block 614, which other embodiments of the process 600 may include full cut sawing block 620. The full cut sawing block 614 and/or the full cut sawing block 620 may be performed when there is a substrate strip of FCCSPs and may involve cutting the substrate strip into individual packages.

The process 600 ends with a visual inspection block 622 of the resulting FCCSP verifying that the desired results were achieved.

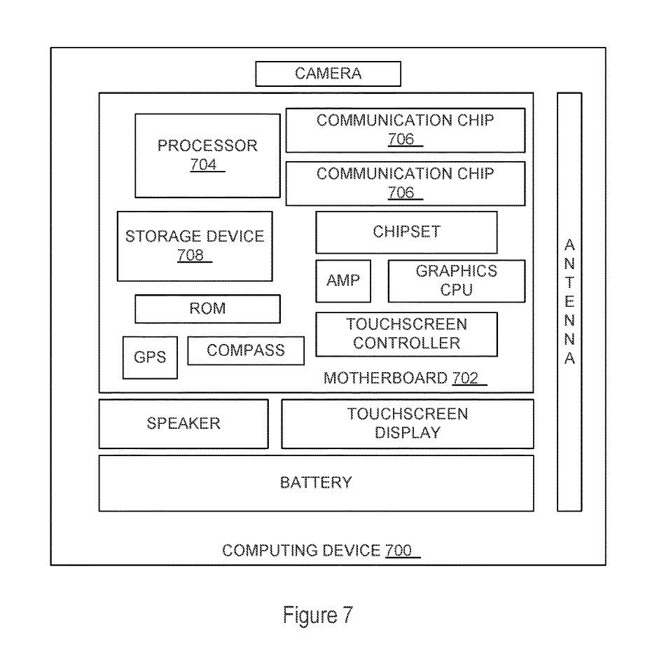

Embodiments of the present disclosure may be implemented into a system using the packages and manufacturing techniques disclosed herein. FIG. 7 schematically illustrates a computing device 700, in accordance with some implementations, which may include one or more FCCSP assemblies, such as the FCCSP assemblies 100, 300, 400, 500, etc., described herein. For instance, chip packages mounted to a motherboard 702 of the computing device 700, such as processor 704, communication chip 706, and storage device 708, may include an FCCSP assembly.

The computing device 700 may be, for example, a mobile communication device or a desktop or rack-based computing device. The computing device 700 may house a board such as the motherboard 702. The motherboard 702 may include a number of components, including (but not limited to) a processor 704 and at least one communication chip 706. Any of the components discussed herein with reference to the computing device 700 may include a heat removal assembly as described above.

The computing device 700 may include a storage device 708. In some embodiments, the storage device 708 may include one or more solid state drives. Examples of storage devices that may be included in the storage device 708 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 700 may include other components that may or may not be physically and electrically coupled to the motherboard 702. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 706 and the antenna may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 706 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other embodiments.

The computing device 700 may include a plurality of communication chips 706. For instance, a first communication chip 706 may be dedicated to shorter range wireless communications such as Wi-Fi and Bluetooth, and a second communication chip 706 may be dedicated to longer range wireless communications such as GPS, EDGE, GPRS, CDMA, WiMAX, LTE, EV-DO, and others. In some embodiments, the communication chip 706 may support wired communications. For example, the computing device 700 may include one or more wired servers.

The processor 704 and/or the communication chip 706 of the computing device 700 may include one or more dies or other components in an IC package. Such an IC package may be coupled with an interposer or another package using any of the techniques disclosed herein. The term “processor” may refer to any device or portion of a device that processes electronic data from registers and/or memory to transform that electronic data into other electronic data that may be stored in registers and/or memory.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data. In some embodiments, the recessed conductive contacts disclosed herein may be implemented in a high-performance computing device.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

1. An apparatus, comprising:
a flip-chip chip scale package (FCCSP); and
a thermal dissipation layer, applied to a surface of the FCCSP through a sputter coating process, to dissipate heat produced by the FCCSP during operation of the FCCSP.

2. The apparatus of claim 1, wherein the thermal dissipation layer includes a copper layer applied to the surface of the FCCSP through the sputter coating process.

3. The apparatus of claim 1, further comprising a flash coat layer applied to a surface of the thermal dissipation layer opposite the FCCSP, wherein the flash coat layer is to protect the thermal dissipation layer from oxidization.

4. The apparatus of claim 1, further comprising an electrolytic plate layer applied to a surface of the thermal dissipation layer opposite the FCCSP, the electrolytic plate layer to increase thermal dissipation of the apparatus.

5. The apparatus of claim 4, wherein a thickness, measured perpendicularly to the surface of the FCCSP, of the electrolytic plate layer is selected based on a desired amount of thermal conductivity of the thermal dissipation layer.

6. The apparatus of claim 4, wherein a combined thickness, measured perpendicularly to the surface of the FCCSP, of the FCCSP, the thermal dissipation layer and the electrolytic plate layer is less than approximately 800 micrometers.

7. The apparatus of claim 1, wherein the FCCSP is for broadband or digital use.

8. The apparatus of claim 1, wherein a combined height of the FCCSP and the thermal dissipation layer is less than approximately 800 micrometers.

9. The apparatus of claim 1, wherein a maximum thickness of the thermal dissipation layer is approximately 20 micrometers.

10. The apparatus of claim 1, wherein the thermal dissipation layer is electrically isolated from a ground of the FCCSP.

11. The apparatus of claim 1, wherein the thermal dissipation layer extends across an entirety of the surface of the FCCSP.

12. The apparatus of claim 1, wherein the FCCSP includes a capillary underfill material or a molded underfill material.

13. A system, comprising:
a circuit board;
a flip-chip chip scale package (FCCSP) mounted to the circuit board; and
a thermal dissipation layer for dissipation of heat produced by the FCCSP and applied to a surface of the FCCSP by a sputter coating process.

14. The system of claim 13, wherein the FCCSP includes a capillary underfill material.

15. The system of claim 13, wherein the FCCSP includes a molded underfill material.

16. The system of claim 13, wherein the thermal dissipation layer extends across an entirety of the surface of the FCCSP.

17. The system of claim 13, further comprising a ground connection coupled to the FCCSP, wherein the thermal dissipation layer is electrically isolated from the ground connection.

18. The system of claim 13, wherein the FCCSP is for broadband or digital use.

19. The system of claim 13, wherein a combined thickness, measured perpendicularly to the surface of the FCCSP, of the FCCSP and the thermal dissipation layer is less than approximately 800 micrometers.

20. The system of claim 13, further comprising an electrolytic plate layer applied, through an electrolytic plating process, to a surface of the thermal dissipation layer opposite the FCCSP, wherein a thickness, measured perpendicularly to the surface of the FCCSP, of the electrolytic plate layer is selected based on a desired amount of thermal conductivity of the thermal dissipation layer.

21. The system of claim 20, wherein a combined thickness, measured perpendicularly to the surface of the FCCSP, of the FCCSP, the thermal dissipation layer, and the electrolytic plate layer is less than approximately 800 micrometers.

22. The system of claim 13, further comprising a flash coat layer applied to a surface of the thermal dissipation layer opposite the FCCSP, the flash coat layer to protect the thermal dissipation layer from oxidization.

23. The system of claim 13, wherein the thermal dissipation layer includes a copper layer applied to the surface of the FCCSP by the sputter coating process.
